(19) United States
(12) Patent Application Publication
(10) Pub. No.: US 2026/0019045 A1
(43) Pub. Date: Jan. 15, 2026

(54) MEMORY DISTORTION NEUTRALIZATION IN A POWER AMPLIFIER CIRCUIT

(71) Applicant: Qorvo US, Inc., Greensboro, NC (US)

(72) Inventors: Marcus Granger-Jones, Scotts Valley, CA (US); Nadim Khlat, Cugnaux (FR); James M. Retz, Cedar Rapids, IA (US)

(21) Appl. No.: 18/996,256

(22) PCT Filed: Aug. 21, 2023
(86) PCT No.: PCT/US2023/030661

§ 371 Date: Jan. 17, 2025

Related U.S. Application Data
(60) Provisional application No. 63/401,779, filed on Aug. 29, 2022.
(60) Provisional application No. 63/478,752, filed on Jan. 6, 2023.

(51) Int. Cl. H03F 1/26; H03F 3/21; H03F 3/213

(52) U.S. Cl. CPC H03F 1/26; H03F 3/211; H03F 3/213; H03F 2200/451

(57) ABSTRACT

Memory distortion neutralization in a power amplifier circuit (58) is provided. The power amplifier circuit (58) includes one or more amplifier stages (40, 42) each configured to amplify a radio frequency (RF) signal based on a time-variant modulated voltage received at a respective collector node. Notably, each of the amplifier stages (40, 42) can inherently cause a derivative of the time-variant modulated voltage (a.k.a. a modulated current) to be leaked from the respective collector node into a respective input node, which can create unwanted remodulation terms that can degrade an adjacent channel leakage ratio (ACLR) of the power amplifier circuit (58). Herein, a neutralization circuit (54, 60) is configured to inject a neutralization current to the respective input node to cancel at least a portion of the leaked modulated current.

### RELATED APPLICATIONS

This application claims the benefit of U.S. provisional patent application Ser. No. 63/401,779, filed on Aug. 29, 2022, and the benefit of U.S. provisional patent application Ser. No. 63/478,752, filed on Jan. 6, 2023, the disclosures of which are hereby incorporated herein by reference in their entireties.

### FIELD OF THE DISCLOSURE

The technology of the disclosure relates generally to neutralizing memory distortion in a power amplifier circuit.

### BACKGROUND

Mobile communication devices have become increasingly common in current society for providing wireless communication services. The prevalence of these mobile communication devices is driven in part by the many functions that are now enabled on such devices. Increased processing capability in such devices means that mobile communication devices have evolved from being pure communication tools into sophisticated mobile multimedia centers that enable enhanced user experiences.

The redefined user experience relies on a higher data rate offered by advanced fifth generation (5G) and 5G new radio (5G-NR) systems, in which a transmission circuit typically amplifies a radio frequency (RF) to a higher power before transmission. In a typical transmission circuit, a transceiver circuit is configured to generate the RF signal, a power management circuit is configured to generate a modulated voltage, a power amplifier circuit is configured to amplify the RF signal based on the modulated voltage, and an antenna circuit is configured to radiate the RF signal in one or more RF frequencies.

The RF signal transmitted in the 5G and 5G-NR systems is subject to stringent adjacent channel leakage ratio (ACLR) requirements imposed by standard bodies and/or regulatory authorities. The ACLR defines a ratio between a power of the RF signal transmitted on an intended radio channel and the power of the RF signal received in an unintended adjacent radio channel. Given that the ACLR of a wideband RF signal can be largely dominated by a remodulation term(s), such as a third order intermodulation product (IMD3), it is thus desirable to improve IMD3 performance of the transmission circuit to thereby improve the ACLR.

### SUMMARY

Embodiments of the disclosure relate to memory distortion neutralization in a power amplifier circuit. The power amplifier circuit includes one or more amplifier stages each configured to amplify a radio frequency (RF) signal based on a time-variant modulated voltage received at a respective collector node. Notably, each of the amplifier stages can inherently cause a derivative of the time-variant modulated voltage (a.k.a. a modulated current) to be leaked from the respective collector node into a respective input node, which can create unwanted remodulation terms that can degrade an adjacent channel leakage ratio (ACLR) of the power amplifier circuit. Moreover, as the derivative of the time-variant modulated voltage, the unwanted remodulation terms often have a memory effect that is difficult to be compensated through, for example, digital predistortion. In embodiments disclosed herein, a neutralization circuit(s) is provided in the power amplifier circuit to inject a neutralization current to the respective input node to cancel at least a portion of the leaked modulated current. By neutralizing the leaked modulated current, it is possible to suppress the unwanted modulation terms, thus helping to improve the ACLR of the power amplifier circuit.

In one aspect, a power amplifier circuit is provided. The power amplifier circuit includes an input-stage amplifier. The input-stage amplifier is configured to receive an RF signal via an input-stage input node and a time-variant modulated voltage via an input-stage collector node. The input-stage amplifier is also configured to amplify the RF signal based on the time-variant modulated voltage received via the input-stage collector node. The power amplifier circuit also includes an output-stage amplifier. The output-stage amplifier is coupled to the input-stage amplifier and configured to receive the RF signal amplified by the input-stage amplifier via an output-stage input node and the time-variant modulated voltage via an output-stage collector node. The output-stage amplifier is also configured to further amplify the RF signal based on the time-variant modulated voltage received via the output-stage collector node. The power amplifier circuit also includes an output-stage neutralization circuit. The output-stage neutralization circuit is coupled to the output-stage collector node and the output-stage input node. The output-stage neutralization circuit is configured to generate an output-stage neutralization current based on the time-variant modulated voltage received via the output-stage collector node to thereby suppress a modulated output-stage current leaked from the output-stage collector node into the output-stage input node.

In another aspect, a method for neutralizing memory distortion in a power amplifier circuit is provided. The method includes amplifying an RF signal received via an input-stage input node based on a time-variant modulated voltage received via an input-stage collector node. The method also includes further amplifying the RF signal received via an output-stage input node based on the time-variant modulated voltage received via an output-stage collector node. The method also includes generating an output-stage neutralization current based on the time-variant modulated voltage received via the output-stage collector node to thereby suppress a modulated output-stage current leaked from the output-stage collector node into the output-stage input node.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an existing transmission circuit that can suffer a degraded adjacent channel leakage ratio (ACLR) performance due to memory distortion caused by a power amplifier circuit in a radio frequency (RF) signal;

FIG. 1B is a schematic diagram illustrating an inner structure of an amplifier stage (e.g., an output-stage) in the power amplifier circuit in FIG. 1A;

FIG. 2 is a schematic diagram of an exemplary power amplifier circuit configured according to an embodiment of the present disclosure to neutralize a memory distortion;

FIG. 3 is a schematic diagram of an exemplary power amplifier circuit configured according to another embodiment of the present disclosure to neutralize the memory distortion;

FIGS. 4A and 4B are schematic diagrams providing exemplary illustrations as to how the power amplifier circuits of FIGS. 2 and 3 can further reduce capacitive loading of the power amplifier circuit in addition to neutralizing the memory distortion;

FIG. 5 is a schematic diagram of an exemplary user element wherein the power amplifier circuits of FIGS. 2 and 3 can be provided; and

FIG. 6 is a flowchart of an exemplary process that can be employed by the power amplifier circuits in FIGS. 2 and 3 to neutralize the memory distortion.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” 10 includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to memory distortion neutralization in a power amplifier circuit. The power amplifier circuit includes one or more amplifier stages each configured to amplify a radio frequency (RF) signal based on a time-variant modulated voltage received at a respective collector node. Notably, each of the amplifier stages can inherently cause a derivative of the time-variant modulated voltage (a.k.a. a modulated current) to be leaked from the respective collector node into a respective input node, which can create unwanted remodulation terms that can degrade an adjacent channel leakage ratio (ACLR) of the power amplifier circuit. Moreover, as the derivative of the time-variant modulated voltage, the unwanted remodulation terms often have a memory effect that is difficult to be compensated through, for example, digital predistortion. In embodiments disclosed herein, a neutralization circuit(s) is provided in the power amplifier circuit to inject a neutralization current to the respective input node to cancel at least a portion of the leaked modulated current. By neutralizing the leaked modulated current, it is possible to suppress the unwanted modulation terms, thus helping to improve the ACLR of the power amplifier circuit.

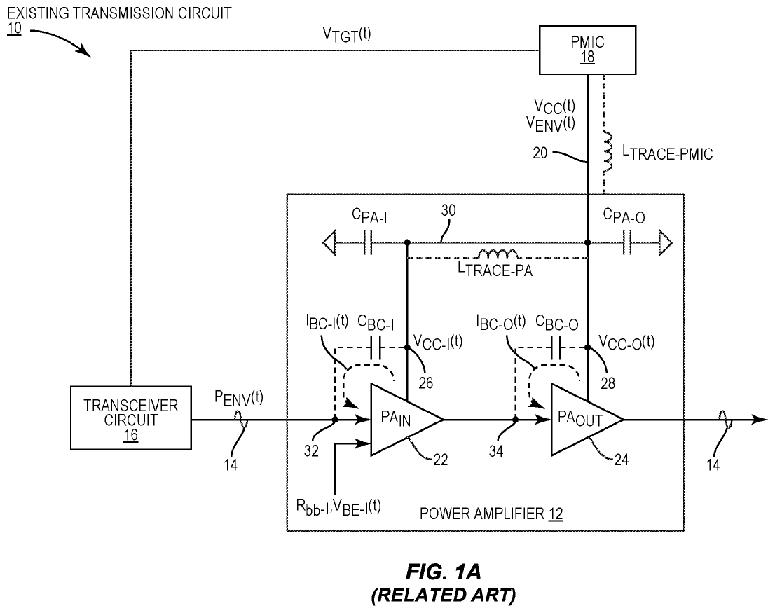

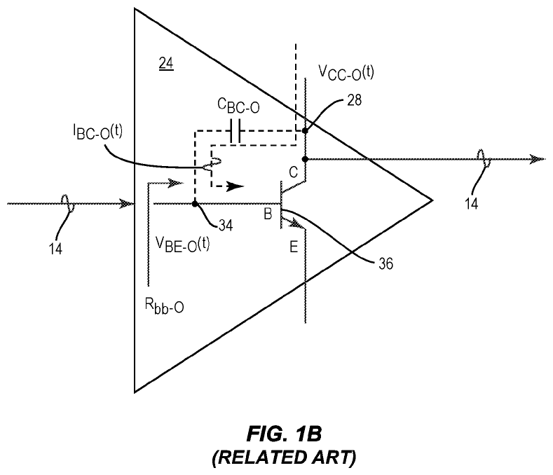

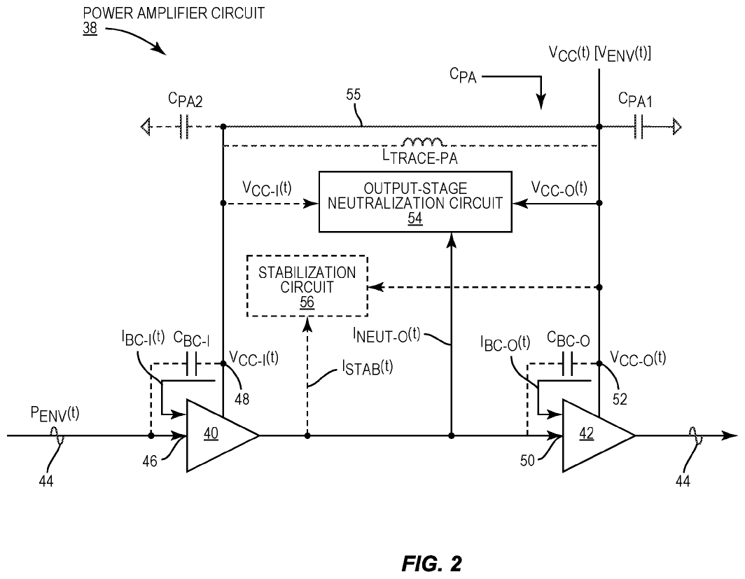

Before discussing the power amplifier circuit according to the present disclosure, starting at FIG. 2, a brief discussion of an existing power amplifier circuit is first provided with reference to FIGS. 1A and 1B to help understand how a memory distortion may be created at a collector node(s) of a power amplifier circuit.

FIG. 1A is a schematic diagram of an exemplary existing transmission circuit 10 that can suffer degraded ACLR performance due to memory distortion caused by a power amplifier circuit 12 in an RF signal 14. The existing transmission circuit 10 includes a transceiver circuit 16 and a power management integrated circuit (PMIC) 18. The transceiver circuit 16 is configured to generate and provide the RF signal 14 to the power amplifier circuit 12. The transceiver circuit 16 is also configured to generate a time-variant target voltage V_{TGT}(t) according to a time-variant power envelope P_{ENV}(t) of the RF signal 14 and provide the time-variant target voltage V_{TGT}(t) to the PMIC 18. The PMIC 18 is configured to generate a time-variant modulated voltage V_{CC}(t), such as an envelope tracking (ET) modulated voltage or an average power tracking (APT) modulated voltage, based on the time-variant target voltage V_{TGT}(t). Notably, since the time-variant modulated voltage V_{CC}(t) is generated based on the time-variant target voltage V_{TGT}(t) and the time-variant target voltage V_{TGT}(t) is generated according to the time-variant power envelope P_{ENV}(t) of the RF signal 14, the time-variant modulated voltage V_{CC}(t) is thus associated with a time-variant voltage envelope V_{ENV}(t) that tracks the time-variant power envelope P_{ENV}(t) of the RF signal 14. The PMIC 18 is configured to provide the time-variant modulated voltage V_{CC}(t) to the power amplifier circuit 12 via an external conductive trace 20, which is associated with a respective equivalent inductive impedance L_{TRACE-PMIC}.

Herein, the power amplifier circuit 12 is a multi-stage power amplifier that includes an input-stage 22 (denoted as “PA_{IN}”) and an output-stage 24 (denoted as “PA_{OUT}”). The input-stage 22 is configured to receive the time-variant modulated voltage V_{CC}(t) at an input-stage collector node 26 (also denoted as “V_{CC-I}(t)”) and the output-stage 24 is configured to receive the time-variant modulated voltage V_{CC}(t) at an output-stage collector node 28 (also denoted as “V_{CC-O}(t)”). The output-stage collector node 28 is coupled to the input-stage collector node 26 via an internal conductive trace 30. Like the external conductive trace 20, the internal conductive trace 30 is also associated with a respective equivalent inductive impedance L_{TRACE-PA}. As such, the time-variant modulated voltage V_{CC}(t) received at the input-stage collector node 26 can be different from the time-variant modulated voltage V_{CC}(t) received at the output-stage collector node 28 in phase and/or amplitude.

The input-stage 22 is configured to receive the RF signal 14 via an input-stage input node 32 and amplify the RF signal 14 based on the time-variant modulated voltage V_{CC}(t) received at the input-stage collector node 26. The output-stage 24 is configured to receive the RF signal 14, as already amplified by the input-stage 22, via an output-stage input node 34. Accordingly, the output-stage 24 will further amplify the RF signal 14 based on the time-variant modulated voltage V_{CC}(t) received at the output-stage collector node 28.

The input-stage 22 has a respective linear parasitic capacitance between the input-stage collector node 26 and the input-stage input node 32, as denoted by a respective equivalent capacitor C_{BC-I}. Likewise, the output-stage 24 has a respective linear parasitic capacitance between the output-stage collector node 28 and the output-stage input node 34, as denoted by a respective equivalent capacitor C_{BC-O}. Herein, the equivalent capacitors C_{BC-I} and C_{BC-O} can both be linear capacitors, as opposed to being non-linear capacitors. As discussed in detail in FIG. 1B, the equivalent capacitor C_{BC-I} and/or the equivalent capacitor C_{BC-O} are the main contributor to the memory distortion in the RF signal 14.

FIG. 1B is a schematic diagram illustrating an inner structure of the output-stage 24 in the power amplifier circuit 12 in FIG. 1A. Common elements between FIGS. 1A and 1B are shown therein with common element numbers and will not be re-described herein.

The output-stage 24 can include a respective transistor 36, such as a bipolar junction transistor (BJT) or a complementary metal-oxide semiconductor (CMOS) transistor. Taking the BJT as an example, the transistor 36 can include a base electrode B, a collector electrode C, and an emitter electrode E. The collector electrode C is coupled to the output-stage collector node 28 to receive the time-variant modulated voltage V_{CC-O}(t).

As an example, the time-variant modulated voltage V_{CC-O}(t) received at the output-stage collector node 28 can include both linear terms and non-linear terms, as expressed in equation (Eq. 1) below.

$${V}_{CC - O ( t )} = {V}_{DC} + A \times {V}_{ENV ( t )} + B \times {V}_{{ENV ( t )}^{2}} + C \times {V}_{{ENV ( t )}^{3}} + … \qquad ( Eq . 1 )$$

In the equation (Eq. 1), V_{DC} represents a constant direct-current (DC) voltage, A×V_{ENV}(t) represents the linear term, and B×V_{ENV}(t) 2+C×V_{ENV}(t) 3+ . . . represents the non-linear term. Studies have shown that the time-variant modulated voltage V_{CC-O}(t) is dominated by the linear term A×V_{ENV}(t). As such, the time-variant modulated voltage V_{CC-O}(t) can be linearly approximated by equation (Eq. 2).

$${V}_{CC - O} ( t ) \approx {V}_{DC} + A \times {V}_{ENV} ( t ) \qquad ( Eq . 2 )$$

When the time-variant modulated voltage V_{CC-O}(t) is applied across the equivalent capacitor C_{BC-O} between the output-stage collector node 28 and the output-stage input node 34, a modulated output-stage current I_{BC-O}(t) is injected from the output-stage collector node 28 into the output-stage input node 34. As shown in equation (Eq. 3) below, the modulated output-stage current I_{BC-O}(t) is largely a linearly modulated current.

$${I}_{CB - O} ( t ) \approx {C}_{BC - O} \times A \times {dV}_{ENV} ( t ) / dt \qquad ( Eq . 3 )$$

The modulated output-stage current I_{BC-O}(t) is converted by an output-stage net impedance R_{bb-O} presenting at the base electrode B of the output-stage 24 into a voltage R_{bb-O}×I_{CB-O}(t), which is then added to the RF signal 14 at the base electrode B of the transistor 36 to create a distorted base voltage V_{BE-O}(t), as shown in equation (Eq. 4) below.

$${V}_{BE - O} ( t ) \approx {V}_{ENV} ( t ) \times {K}_{RF} \times sin ( ω ct + φ ( t ) ) + {{R}_{b b}}_{- O} \times {I}_{CB - O} ( t ) \qquad ( Eq . 4 )$$

In the equation (Eq. 4), K_{RF} represents a dimensionless constant (e.g., a gain). The time-variant voltage envelope V_{ENV}(t) and the RF signal 14 re-modulate through even order (primarily 2^{nd} order) distortion within the output-stage 24 to generate an output-stage distortion product that can be expressed as:

$$K o \times {R}_{bb - O} \times {I}_{CB - O} ( t ) \times {V}_{ENV} ( t ) \times {K}_{R F} \times sin ( ω ct + φ ( t ) )$$

With reference back to FIG. 1A, the specific analysis and issues discussed with respect to the output-stage 24 in FIG. 1B are similarly applicable to the input-stage 22. When the time-variant modulated voltage V_{CC-I}(t) is applied across the equivalent capacitor C_{BC-I} between the input-stage collector node 26 and the input-stage input node 32, a modulated input-stage current I_{BC-I}(t) is injected from the input-stage collector node 26 into the input-stage input node 32. The modulated input-stage current I_{BC-O}(t) is converted by an input-stage net impedance R_{bb-I} presenting at the base electrode B of the input-stage 22 into a voltage R_{bb-I}×I_{CB-I}(t), which is then added to the RF signal 14 at the base electrode B of the transistor 36 to create a distorted base voltage V_{BE-I}(t) at the input-stage 22. The time-variant voltage envelope V_{ENV}(t) and the RF signal 14 re-modulate through higher order distortion within the input-stage 22 to generate an input-stage distortion product that can be expressed as:

$${K}_{I} \times {R}_{bb - I} \times {I}_{CB - I} ( t ) \times {V}_{ENV} ( t ) \times {K}_{RF} \times sin ( ω ct + φ ( t ) )$$

Notably, as a derivative of the time-variant voltage envelope V_{ENV}(t), the input-stage and the output-stage distortion products inherently have a memory, which can be difficult to compensate for by such techniques as isoGain and linear digital predistortion (DPD). As a result, the power amplifier circuit 12 can suffer a degraded ACLR performance. Hence, it is desirable to suppress the input-stage and the output-stage distortion products to help improve ACLR performance of the power amplifier circuit 12.

In this regard, FIG. 2 is a schematic diagram of an exemplary power amplifier circuit 38 configured according to an embodiment of the present disclosure to neutralize the output-stage and/or the input-stage distortions presenting in the power amplifier circuit 12 of the existing transmission circuit 10 of FIG. 1A. According to embodiments described herein, one or more neutralization circuits can be provided in the power amplifier circuit 38 to effectively suppress the output-stage and/or the input-stage distortions within the power amplifier circuit 38. By suppressing the derivative of the time-variant voltage envelope V_{ENV}(t) at inputs to the output-stage and/or the input-stage distortions within the power amplifier circuit 38, it is possible to significantly reduce the memory distortion generated through remodulation between the time-variant voltage envelope V_{ENV}(t) and an RF signal within transistors in the power amplifier circuit 38 and improve ACLR performance (e.g., >6 dB ACLR reduction) of the power amplifier circuit 38 without requiring assistance from associated circuits (e.g., transceiver and PMIC). As a result, the power amplifier circuit 38 may interoperate with transceivers and/or PMICs from different vendors.

The power amplifier circuit 38 includes an input-stage amplifier 40 and an output-stage amplifier 42. The input-stage amplifier 40 is configured to receive an RF signal 44 via an input-stage input node 46. Like the RF signal 14 in FIG. 1A, the RF signal 44 is also associated with a time-variant power envelope P_{ENV}(t). The input-stage amplifier 40 also receives a time-variant modulated voltage V_{CC}(t) via an input-stage collector node 48. Like the time-variant modulated voltage V_{CC}(t) in FIG. 1A, the time-variant modulated voltage V_{CC}(t) received herein is also associated with a time-variant voltage envelope V_{ENV}(t). For the purpose of distinction, the time-variant modulated voltage V_{CC}(t) via the input-stage collector node 48 is hereinafter referred to as a time-variant input-stage voltage V_{CC-I}(t). Accordingly, the input-stage amplifier 40 is configured to amplify the RF signal 44 based on the time-variant input-stage voltage V_{CC-I}(t).

The output-stage amplifier 42 is configured to receive the RF signal 44 amplified by the input-stage amplifier 40 via an output-stage input node 50. The output-stage amplifier 42 also receives the time-variant modulated voltage V_{CC}(t) via an output-stage collector node 52. For the purpose of distinction, the time-variant modulated voltage V_{CC}(t) via the output-stage collector node 52 is hereinafter referred to as a time-variant output-stage voltage V_{CC-O}(t). Accordingly, the output-stage amplifier 42 is configured to further the RF signal 44, which is already amplified by the input-stage amplifier 40, based on the time-variant output-stage voltage V_{CC-O}(t).

In a non-limiting example, each of the input-stage amplifier 40 and the output-stage amplifier 42 includes the transistor 36 in FIG. 1B. The input-stage amplifier 40 is identical to or functionally equivalent to the input-stage 22 in FIG. 1A. Like the input-stage 22, the input-stage amplifier 40 also has a respective parasitic capacitance between the input-stage collector node 48 and the input-stage input node 46, as denoted by a respective equivalent capacitor C_{BC-I}. Like the equivalent capacitor C_{BC-I} in FIG. 1A, the equivalent capacitor C_{BC-I} herein is also a linear capacitor. Thus, when the time-variant input-stage voltage V_{CC-I}(t) is applied across the equivalent capacitor C_{BC-I}, a modulated input-stage current I_{BC-I}(t) is injected from the input-stage collector node 48 into the input-stage input node 46. As a result, the input-stage amplifier 40 can cause the same input-stage distortion product, K_{I}×R_{bb-I}×I_{CB-I}(t)×V_{ENV}(t)×K_{RF}×sin(ωct+φ(t)), as the input-stage 22 does in FIG. 1A.

The output-stage amplifier 42, on the other hand, is identical to or functionally equivalent to the output-stage 24 in FIG. 1A. Like the output-stage 24, the output-stage amplifier 42 also has a respective parasitic capacitance between the output-stage collector node 52 and the output-stage input node 50, as denoted by a respective equivalent capacitor C_{BC-O}. Like the equivalent capacitor C_{BC-O} in FIG. 1A, the equivalent capacitor C_{BC-O} herein is also a linear capacitor. Thus, the time-variant output-stage voltage V_{CC-O}(t) is applied across the equivalent capacitor C_{BC-O}, a modulated output-stage current I_{BC-O}(t) is injected from the output-stage collector node 52 into the output-stage input node 50. As a result, the output-stage amplifier 42 can cause the same output-stage distortion product, K_{O}×R_{bb-O}×I_{CB-O}(t)×V_{ENV}(t)×K_{RF}×sin(ωct++φ(t)), as the output-stage 24 does in FIG. 1A.

As described previously, the input-stage distortion product and/or the output-stage distortion product can cause the power amplifier circuit 38 to suffer a degraded ACLR performance. As such, to help improve ACLR performance of the power amplifier circuit 38, it is necessary to suppress the input-stage distortion product and/or the output-stage distortion product by neutralizing the derivative of a baseband signal appearing at bases of the input-stage amplifier 40 and/or the output-stage amplifier 42.

In one embodiment, the power amplifier circuit 38 is configured to suppress the output-stage distortion product, K_{O}×R_{bb-O}×I_{CB-O}(t)×V_{ENV}(t)×K_{RF}×sin(ωct+φ(t)), to help improve ACLR performance of the power amplifier circuit 38. In this regard, the power amplifier circuit 38 is configured to further include an output-stage neutralization circuit 54, which is coupled to the output-stage collector node 52 and the output-stage input node 50. Although the output-stage neutralization circuit 54 is shown here as being directly coupled to the output-stage collector node 52, the output-stage neutralization circuit 54 may also be coupled to the output-stage collector node 52 via a low-frequency feed circuit (e.g., an inductor), which is omitted herein for the sake of simplicity. Herein, the output-stage neutralization circuit 54 is configured to generate an output-stage neutralization current I_{NEUT-O}(t) based on the time-variant output-stage voltage V_{CC-O}(t) to thereby suppress the modulated output-stage current I_{BC-O}(t) leaked from the output-stage collector node 52 into the output-stage input node 50. By suppressing the modulated output-stage current I_{BC-O}(t), it is possible to reduce the output-stage distortion product, K_{O}×R_{bb-O}×I_{CB-O}(t)× V_{ENV}(t)×K_{RF}×sin(ωct+φ(t)), to thereby improve ACLR performance in the power amplifier circuit 38.

In another embodiment, the output-stage neutralization circuit 54 may be further coupled to the input-stage collector node 48. In this regard, the output-stage neutralization circuit 54 can be further configured to generate the output-stage neutralization current I_{NEUT-O}(t) based on both the time-variant output-stage voltage V_{CC-O}(t) and the time-variant input-stage voltage V_{CC-I}(t). By further generating the output-stage neutralization current I_{NEUT-O}(t) based on the time-variant input-stage voltage V_{CC-I}(t), it is possible to further overcome a distortion in the time-variant input-stage voltage V_{CC-I}(t) as resulted by a respective equivalent inductive impedance L_{TRACE-PA} associated between an internal conductive trace 55 between the input-stage amplifier 40 and the output-stage amplifier 42.

More specifically, the output-stage neutralization circuit 54 is configured to generate the output-stage neutralization current I_{NEUT-O}(t) that is approximately equal to the modulated output-stage current I_{BC-O}(t) but flows in an opposite direction from the modulated output-stage current I_{BC-O}(t). As shown in FIG. 2, the modulated output-stage current I_{BC-O}(t) flows from the output-stage collector node 52 into the output-stage input node 50, while the output-stage neutralization current I_{NEUT-O}(t) flows out of the output-stage input node 50 toward the output-stage neutralization circuit 54. As such, the output-stage neutralization current I_{NEUT-O}(t) is able to substantially neutralize the modulated output-stage current I_{BC-O}(t) at the output-stage input node 50.

In a non-limiting example, the output-stage neutralization circuit 54 can be configured to generate the output-stage neutralization current I_{NEUT-O}(t) as a linear function of the modulated output-stage current I_{BC-O}(t) according to equation (Eq. 5) below.

$${I}_{N E UT - O} ( t ) = {M}_{0} \times {I}_{BC - O} ( t ) \qquad ( Eq . 5 )$$

$$( {M}_{0} ≦ 1 )$$

By adding the output-stage neutralization current I_{NEUT-O}(t) to the modulated output-stage current I_{BC-O}(t), the output-stage distortion product is changed to K_{O}×R_{b-O}×(1−M₀)×I_{CB-O}(t)×V_{ENV}(t)×K_{RF}×sin(ωct+φ(t)). In this regard, when M₀ is equal to one (1), the output-stage distortion product can be completely cancelled out. Studies have shown that a significant ACLR improvement can be achieved by suppressing even a portion of the output-stage distortion. For example, when M₀ is equal to ¾ (0.75), the power amplifier circuit 38 can achieve approximately 12 dB ACLR improvement. As such, in a real-world implementation, it may be possible to meet a desired ACLR target by cancelling just a portion of the output-stage distortion product. As a result, the output-stage neutralization circuit 54 may not need to be calibrated to generate the output-stage neutralization current I_{NEUT-O}(t) that precisely matches the modulated output-stage current I_{BC-O}(t).

Under certain conditions, such as when the transistor 36 in the output-stage amplifier 42 is operating in a linear region, when the time-variant modulated voltage V_{CC}(t) is an average power tracking (APT) modulated voltage, or when either the time-variant power envelope P_{ENV}(t) or the time-variant voltage envelope V_{ENV}(t) is erroneously absent, the output-stage neutralization circuit 54 may be subject to an instability issue. In this regard, the power amplifier circuit 38 may further include a stabilization circuit 56 that is coupled between the output-stage collector node 52 and the output-stage input node 50. The stabilization circuit 56 can be configured to add a stabilization current I_{STAB}(t) with the output-stage neutralization current I_{NEUT-O}(t) to help prevent low frequency (e.g., <200 MHz) oscillations.

In a non-limiting example, the stabilization circuit 56 can also help suppress a negative real impedance in a frequency that is between a modulation bandwidth of the time-variant power envelope P_{ENV}(t) and a carrier frequency, thus making it possible to generate the output-stage neutralization current I_{NEUT-O}(t) more aggressively (e.g., M₀=1). As an example, the stabilization circuit 56 can be as simple as a resistor-capacitor (RC) circuit coupled between the output-stage collector node 52 and the output-stage input node 50.

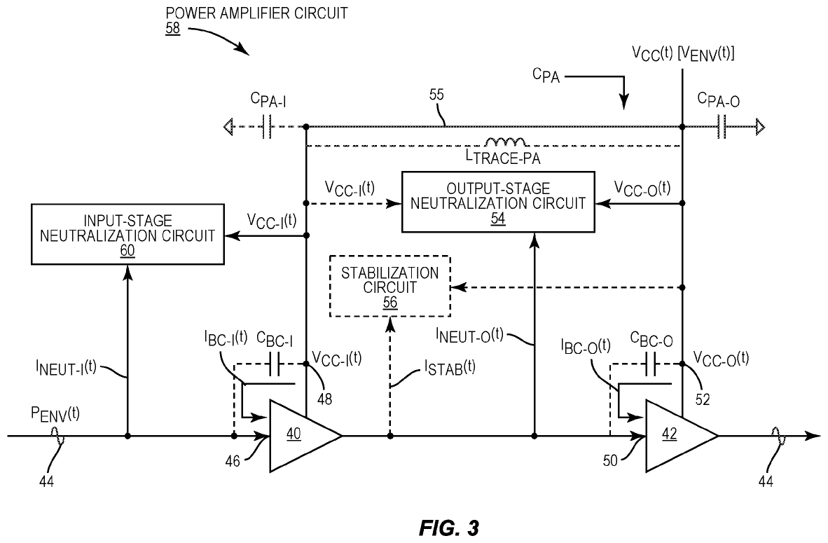

In another embodiment, the power amplifier circuit 38 is configured to suppress both the input-stage distortion product, K_{I}×R_{bb-I}×I_{CB-I}(t)×V_{ENV}(t)×K_{RF}×sin(ωct+φ(t)), and the output-stage distortion product, K_{O}×R_{bb-O}×I_{CB-O}(t)×V_{ENV}(t)×K_{RF}×sin(ωct++φ(t)), to help improve ACLR performance of the power amplifier circuit 38. In this regard, FIG. 3 is a schematic diagram of an exemplary power amplifier circuit 58 configured according to another embodiment of the present disclosure. Common elements between FIGS. 2 and 3 are shown therein with common element numbers and will not be re-described herein.

The power amplifier circuit 58 is further configured to include an input-stage neutralization circuit 60 that is coupled between the input-stage collector node 48 and the input-stage input node 46. Similar to the output-stage neutralization circuit 54, the input-stage neutralization circuit 60 is configured to generate an input-stage neutralization current I_{NEUT}(I(t) based on the time-variant input-stage voltage V_{CC-I}(t) to thereby suppress the modulated input-stage current I_{BC-I}(t) leaked from the input-stage collector node 48 into the input-stage input node 46.

In a non-limiting example, the input-stage neutralization circuit 60 can be configured to generate the input-stage neutralization current I_{NEUT-I}(t) as a linear function of the modulated input-stage current I_{BC-I}(t) according to equation (Eq. 6) below.

$${I}_{NEUT - I} ( t ) = {M}_{1} \times {I}_{BC - I} ( t ) \qquad ( Eq . 6 )$$

$$( {M}_{1} ≦ 1 )$$

By adding the input-stage neutralization current I_{NEUT-I}(t) to the modulated input-stage current I_{BC-I}(t), the input-stage distortion product is changed to K₁×R_{bb-I}×(1−M₁)×I_{CB-I}(t)×V_{ENV}(t)×K_{RF}×sin(ωct++φ(t)). In this regard, when M₁ is equal to one (1), the input-stage distortion product can be completely cancelled out. Further, by including the input-stage neutralization circuit 60 to suppress the input-stage distortion product, it is possible to prevent intermodulation between the input-stage distortion product and the output-stage distortion product at the output-stage amplifier 42, which will cause a cascaded higher order memory distortion. Such higher order memory distortion can become significant and problematic in ACLR2 (a.k.a. “alternate ACLR”).

With reference back to FIG. 2, adding the output-stage neutralization circuit 54, with or without the input-stage neutralization circuit 60 in FIG. 3, can also help reduce a capacitive loading C_{PA} presented to the time-variant modulated voltage V_{CC}(t) at a modulation frequency of the time-variant voltage envelope V_{ENV}(t) by the power amplifier circuit 38. Recall that the power amplifier circuit 12 in FIG. 1A is coupled to the PMIC 18 via an external conductive trace 20 and the external conductive trace 20 is associated with the equivalent inductive impedance L_{TRACE-PMIC}. Similarly, when the power amplifier circuit 38 is coupled to a PMIC (not shown), the conductive path between the PMIC and the power amplifier circuit 38 will likewise have a respective equivalent inductive impedance. Thus, the capacitive loading C_{PA} and the equivalent inductive impedance can form a second order filter that can potentially distort the time-variant modulated voltage V_{CC}(t). As such, when the RF signal 44 is generated with a higher modulation bandwidth (e.g., ≥100 MHz), it is highly desirable to minimize the capacitive loading C_{PA} to less than one hundred picofarad (<100 pF) such that an equalization filter (not shown) in the PMIC 18 can effectively compensate for the filtering effect of the second order filter.

Unfortunately, the capacitive loading C_{PA} of the power amplifier circuit 38 is typically between 150-170 pF, among which approximately 90 pF is contributed by a decoupling capacitor C_{PA1} or C_{PA2}. The remaining 60-80 pF results from a so-called multiplication effect of the equivalent capacitor C_{BC-O} and/or the equivalent capacitor C_{BC-I}. Thus, to reduce the capacitive loading C_{PA} to below 100 pF, it would be necessary to minimize the multiplication effect caused by the equivalent capacitor C_{BC-O} and/or the equivalent capacitor C_{BC-I}.

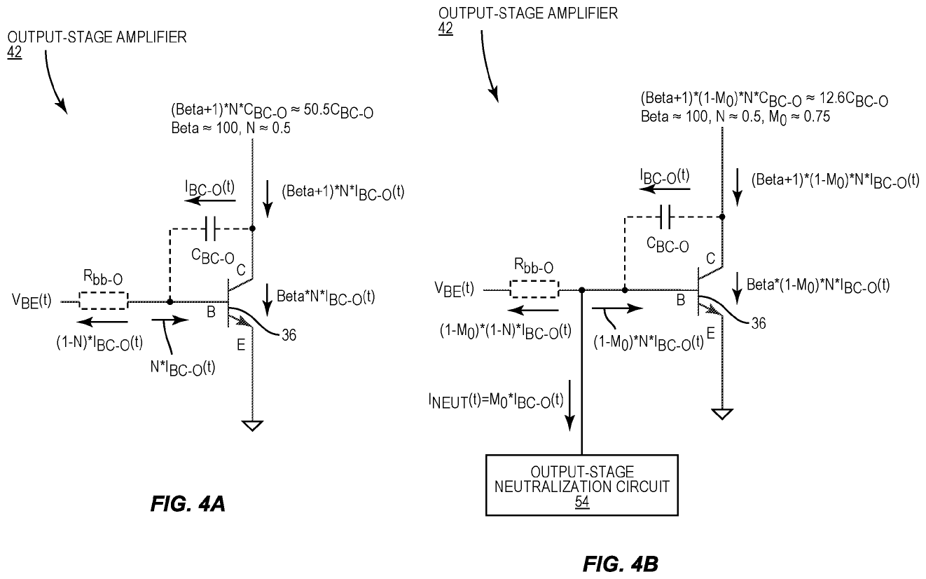

FIG. 4A is a schematic diagram illustrating the multiplication effect resulting from the equivalent capacitor C_{BC-O} of the output-stage amplifier 42 in FIG. 2, which includes the transistor 36 in FIG. 1B, when the output-stage amplifier 42 is not coupled to the output-stage neutralization circuit 54. In contrast, FIG. 4B is a schematic diagram illustrating how the multiplication effect resulting from the equivalent capacitor C_{BC-O} of the output-stage amplifier 42 in FIG. 2 can be reduced by the output-stage neutralization circuit 54. Common elements between FIGS. 1B, 2, 4A, and 4B are shown therein with common element numbers and will not be re-described herein.

As shown in FIG. 4A, the equivalent capacitor C_{BC-O} contributes a capacitance that approximately equals 50.5*C_{BC-O} to the capacitive loading C_{PA} if the output-stage neutralization circuit 54 is not provided in the power amplifier circuit 38. In contrast as shown in FIG. 4B, by adding the output-stage neutralization circuit 54 in the power amplifier circuit 38, the equivalent capacitor C_{BC-O} will instead contribute approximately 12.6*C_{BC-O} equal to the capacitive loading C_{PA}. In this regard, adding the output-stage neutralization circuit 54 in the power amplifier circuit 38 can reduce the multiplication effect by a factor of four (4) or even more (with a higher M₀ value). As a result, it is possible to reduce the capacitive loading C_{PA} to less than or equal to 100 pF.

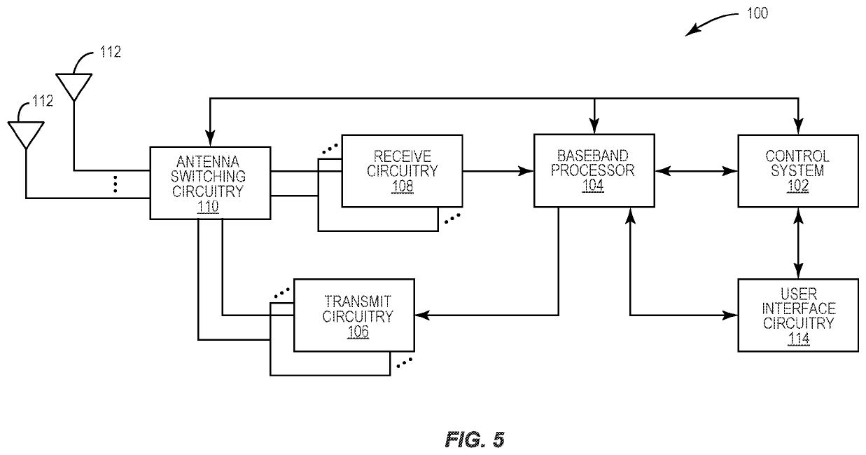

The power amplifier circuit 38 of FIG. 2 and the power amplifier circuit 58 of FIG. 3 can be provided in a user element to enable memory distortion neutralization according to embodiments described above. In this regard, FIG. 5 is a schematic diagram of an exemplary user element 100 wherein the power amplifier circuit 38 of FIG. 2 and the power amplifier circuit 58 of FIG. 3 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

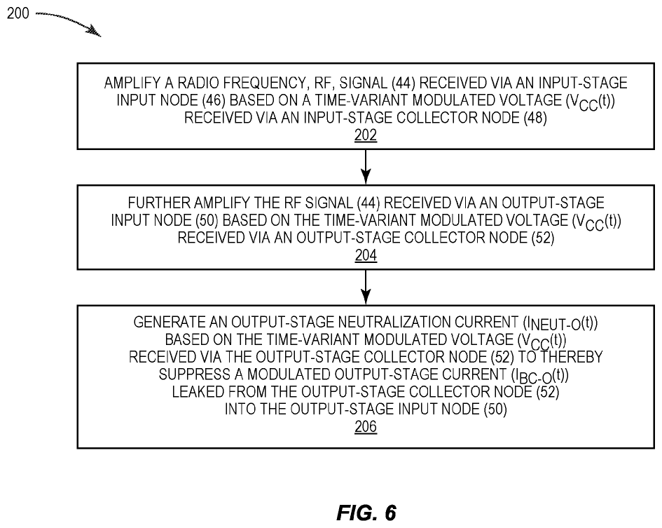

In an embodiment, the power amplifier circuit 38 of FIG. 2 and the power amplifier circuit 58 of FIG. 3 can be configured to neutralize the memory distortion based on a process. In this regard, FIG. 6 is a flowchart of an exemplary process 200 that can be employed by the power amplifier circuit 38 of FIG. 2 and the power amplifier circuit 58 of FIG. 3 to neutralize the memory distortion.

Herein, the input-stage amplifier 40 is configured to amplify the RF signal 44, which is received via the input-stage input node 46, based on the time-variant modulated voltage V_{CC}(t) received via the input-stage collector node 48 (step 202). The output-stage amplifier 42 is configured to further amplify the RF signal 44, which has been amplified by the input-stage amplifier 40 and is received via the output-stage input node 50, based on the time-variant modulated voltage V_{CC}(t) received via the output-stage collector node 52 (step 204). The output-stage neutralization circuit 54 is configured to generate the output-stage neutralization current I_{NEUT-O}(t) based on the time-variant modulated voltage V_{CC}(t), as received via the output-stage collector node 52, to thereby suppress the modulated output-stage current I_{BC-O}(t) leaked from the output-stage collector node 52 into the output-stage input node 50 (step 206).

Those skilled in the art will recognize improvements and modifications to the preferred embodiments of the present disclosure. All such improvements and modifications are considered within the scope of the concepts disclosed herein and the claims that follow.

1. A power amplifier circuit comprising:
an input-stage amplifier configured to:
receive a radio frequency, RF, signal via an input-stage input node and a time-variant modulated voltage via an input-stage collector node; and
amplify the RF signal based on the time-variant modulated voltage received via the input-stage collector node;
an output-stage amplifier coupled to the input-stage amplifier and configured to:
receive the RF signal amplified by the input-stage amplifier via an output-stage input node and the time-variant modulated voltage via an output-stage collector node; and
further amplify the RF signal based on the time-variant modulated voltage received via the output-stage collector node; and
an output-stage neutralization circuit coupled to the output-stage collector node and the output-stage input node, the output-stage neutralization circuit is configured to generate an output-stage neutralization current based on the time-variant modulated voltage received via the output-stage collector node to thereby suppress a modulated output-stage current leaked from the output-stage collector node into the output-stage input node.

2. The power amplifier circuit of claim 1, further comprising a stabilization circuit coupled between the output-stage collector node and the output-stage input node, the stabilization circuit is configured to add a stabilization current with the output-stage neutralization current.

3. The power amplifier circuit of claim 1, wherein the output-stage neutralization circuit is further coupled to the input-stage collector node and configured to generate the output-stage neutralization current based on the time-variant modulated voltage received via the output-stage collector node and the time-variant modulated voltage received via the input-stage collector node.

4. The power amplifier circuit of claim 3, further comprising a stabilization circuit coupled between the output-stage collector node and the output-stage input node, the stabilization circuit is configured to add a stabilization current with the output-stage neutralization current.

5. The power amplifier circuit of claim 1, wherein the modulated output-stage current is proportionally related to a linear parasitic capacitance between the output-stage collector node and the output-stage input node.

6. The power amplifier circuit of claim 1, wherein:
the time-variant modulated voltage received at the output-stage collector node comprises a linear term and a plurality of non-linear terms; and
the output-stage neutralization circuit is further configured to generate the output-stage neutralization current based on the linear term of the time-variant modulated voltage received at the output-stage collector node.

7. The power amplifier circuit of claim 1, further comprising an input-stage neutralization circuit coupled between the input-stage collector node and the input-stage input node, the input-stage neutralization circuit is configured to generate an input-stage neutralization current based on the time-variant modulated voltage received via the input-stage collector node to thereby suppress a modulated input-stage current leaked from the input-stage collector node into the input-stage input node.

8. The power amplifier circuit of claim 7, further comprising a stabilization circuit coupled between the output-stage collector node and the output-stage input node, the stabilization circuit is configured to add a stabilization current with the output-stage neutralization current.

9. The power amplifier circuit of claim 7, wherein the modulated input-stage current is proportionally related to a linear parasitic capacitance between the input-stage collector node and the input-stage input node.

10. The power amplifier circuit of claim 7, wherein:
the time-variant modulated voltage received at the input-stage collector node comprises a linear term and a plurality of non-linear terms; and
the input-stage neutralization circuit is further configured to generate the input-stage neutralization current based on the linear term of the time-variant modulated voltage received at the input-stage collector node.

11. A method for neutralizing memory distortion in a power amplifier circuit comprising:
amplifying a radio frequency, RF, signal received via an input-stage input node based on a time-variant modulated voltage received via an input-stage collector node;
further amplifying the RF signal received via an output-stage input node based on the time-variant modulated voltage received via an output-stage collector node; and
generating an output-stage neutralization current based on the time-variant modulated voltage received via the output-stage collector node to thereby suppress a modulated output-stage current leaked from the output-stage collector node into the output-stage input node.

12. The method of claim 11, further comprising adding a stabilization current with the output-stage neutralization current.

13. The method of claim 11, further comprising generating the output-stage neutralization current based on the time-variant modulated voltage received via the output-stage collector node and the time-variant modulated voltage received via the input-stage collector node.

14. The method of claim 13, further comprising adding a stabilization current with the output-stage neutralization current.

15. The method of claim 11, further comprising generating the modulated output-stage current to be proportionally related to a linear parasitic capacitance between the output-stage collector node and the output-stage input node.

16. The method of claim 11, further comprising:
receiving the time-variant modulated voltage at the output-stage collector node that comprises a linear term and a plurality of non-linear terms; and
generating the output-stage neutralization current based on the linear term of the time-variant modulated voltage received at the output-stage collector node.

17. The method of claim 11, further comprising generating an input-stage neutralization current based on the time-variant modulated voltage received via the input-stage collector node to thereby suppress a modulated input-stage current leaked from the input-stage collector node into the input-stage input node.

18. The method of claim 17, further comprising adding a stabilization current with the output-stage neutralization current.

19. The method of claim 17, further comprising generating the modulated input-stage current to be proportionally related to a linear parasitic capacitance between the input-stage collector node and the input-stage input node.

20. The method of claim 17, further comprising:
receiving the time-variant modulated voltage at the input-stage collector node that comprises a linear term and a plurality of non-linear terms; and
generating the input-stage neutralization current based on the linear term of the time-variant modulated voltage received at the input-stage collector node.
